(19) United States
(12) Patent Application Publication
(10) Pub. No.: US 2023/0290909 A1
(43) Pub. Date: Sep. 14, 2023

(54) DISPLAY PIXELS MADE FROM STACKED MICRO-LED STRUCTURES AND PHOTOLUMINESCENT MATERIALS

(71) Applicant: Applied Materials, Inc., Santa Clara, CA (US)

(72) Inventors: Zhiyong Li, Foster City, CA (US); Mingwei Zhu, San Jose, CA (US); Hou T. Ng, Campbell, CA (US); Nag Patibandla, Pleasanton, CA (US); Lisong Xu, San Jose, CA (US); Kai Ding, Fremont, CA (US); Sivapackia Ganapathiappan, Los Altos, CA (US)

(73) Assignee: Applied Materials, Inc., Santa Clara, CA (US)

(21) Appl. No.: 18/182,856

(22) Filed: Mar. 13, 2023

Related U.S. Application Data
(60) Provisional application No. 63/318,871, filed on Mar. 11, 2022.

(51) Int. Cl. H01L 33/50; H01L 33/00; H01L 25/075

(52) U.S. Cl. CPC H01L 33/502; H01L 33/005; H01L 25/0753; H01L 2933/0041

(57) ABSTRACT

Exemplary pixel structures are described that include a first light emitting diode structure, operable to generate blue light characterized by a peak emission wavelength of greater than or about 450 nm, and a second light emitting diode structure positioned on the first light emitting diode structure. The second light emitting diode structure is operable to generate ultraviolet light characterized by a peak emission wavelength of less than or about 380 nm. The pixel structures may also include a photoluminescent region, containing a photoluminescent material, that is positioned on the second light emitting diode structure.

### CROSS-REFERENCE TO RELATED APPLICATION

This application claims the benefit of U.S. Provisional No. 63/318,871 filed on Mar. 11, 2022, entitled “DISPLAY PIXELS MADE FROM STACKED MICRO-LED STRUCTURES AND PHOTOLUMINESCENT MATERIALS,” the entire contents of which are incorporated herein by reference.

### TECHNICAL FIELD

The present technology relates to pixels that include at least one subpixel with a stacked micro-light-emitting-diode (μLED) structure combined with photoluminescent materials. Exemplary photoluminescent materials include quantum dots.

### BACKGROUND

High-resolution light-emitting diode (LED) displays can include millions of micron-sized pixels arranged to form a viewing screen. Conventional LED displays generate a color image by filtering down white light from an LED light source into red, green, and blue pixels that emit at varying intensities across the viewing screen. Other LED displays excite organic or inorganic compounds so they emit light of a particular color, such as red, green, or blue light, depending on the pixel. These LED displays typically require fewer filters to block the light of unwanted colors, which can improve their brightness and power efficiency. However, there can be wide variations in the emission characteristics and lifetimes of the light-emitting materials, making it difficult to display images with an accurate color gamut and stable, consistent color characteristics over a long lifetime.

Thus, there is a need for pixel designs that generate accurate and stable colors for display devices that include excitable light-emitting materials. These and other needs are addressed by the present technology.

### SUMMARY

Embodiments of the present technology include pixel structures that include a first light emitting diode structure, operable to generate blue light characterized by a peak emission wavelength of greater than or about 450 nm, and a second light emitting diode structure positioned on the first light emitting diode structure. The second light emitting diode structure is operable to generate ultraviolet light characterized by a peak emission wavelength of less than or about 405 nm.

In additional embodiments, the pixel structures also include a photoluminescent region, containing a photoluminescent material, that is positioned on the second light emitting diode structure. The photoluminescent material includes a red quantum dot material or a green quantum dot material, and the pixel structures are free of a blue quantum dot material. In still further embodiments, the pixel structure further includes a backplane in electronic communication with the first light emitting diode structure or the second light emitting diode structure. In yet additional embodiments, the backplane is operable to activate only one of the first light emitting diode structure and the second light emitting diode structure. In yet further embodiments, the first light emitting diode structure includes a blue quantum well stack, operable to emit the blue light, and the second light emitting diode structure includes a UV quantum well stack operable to emit the ultraviolet light. In more embodiments, the pixel structure further includes a UV light filter positioned on the photoluminescent region of the pixel structure. In still more embodiments, the pixel structure further includes a microlens posited on the UV light filter.

Embodiments of the present technology include additional pixel structures that include subpixels. The pixel structures include a first subpixel that includes an ultraviolet light emitting diode structure operable to generate ultraviolet light characterized by a peak emission wavelength of less than or about 405 nm. The first subpixel also includes a photoluminescent region, positioned on the ultraviolet light emitting diode structure, containing a photoluminescent material operable to emit red or green light. The pixel structure also includes a second subpixel that includes a blue light emitting diode structure, operable to generate blue light characterized by a peak emission wavelength of greater than or about 450 nm, and a non-photoluminescent region positioned on the blue light emitting diode. The non-photoluminescent region is free of a photoluminescent material.

In additional embodiments, the non-photoluminescent region has the same volume as the photoluminescent region. In further embodiments, the first subpixel further includes a blue light emitting diode structure positioned on an opposite side of the ultraviolet light emitting diode structure as the photoluminescent region. In still further embodiments, the second subpixel further includes an ultraviolet light emitting diode structure positioned between the blue light emitting diode structure and the non-photoluminescent region. In yet additional embodiments, the pixel structure further includes a backplane in electronic communication with the ultraviolet light emitting diode structure of the first subpixel and disconnected from the blue light emitting diode structure of the first subpixel. In more embodiments, the pixel structure is free of a blue quantum dot material.

Embodiments of the present technology still further include methods of fabricating a pixel. The methods include forming a blue light emitting diode structure on a substrate. The methods further include forming an ultraviolet light emitting diode structure on the blue light emitting diode structure to make a stacked light emitting diode structure. The methods additionally include forming a photoluminescent region on the stacked light emitting diode structure. A photoluminescent precursor is deposited in the photoluminescent region, and the photoluminescent precursor is cured to form a photoluminescent material. The photoluminescent material is operable to emit red or green light.

In additional embodiments, the methods further include adding an additional subpixel to the pixel, where the additional subpixel is formed by forming an additional blue light emitting diode structure on the substrate. An additional ultraviolet light emitting diode structure is formed on the additional blue light emitting diode structure to make an additional stacked light emitting diode structure. The methods also include forming an additional photoluminescent region on the stacked light emitting diode structure and forming a UV light filter on the additional photoluminescent region. The additional photoluminescent region is free of a photoluminescent material, and the additional subpixel is operable to emit blue light from the additional blue light emitting diode structure.

In further embodiments, the pixel is free of a blue quantum dot material. In still further embodiments, the methods also include contacting a backplane to a side of the stacked light emitting diode structure that is opposite a side in contact with the substrate. The backplane is operable to be in electronic communication with the stacked light emitting diode structure. The methods further include removing the substrate from the stacked light emitting diode structure and forming the photoluminescent region on the side of the stacked light emitting diode structure where the substrate is removed. In more embodiments, the method yet also includes forming a UV light filter on the photoluminescent region containing the photoluminescent material. In still more embodiments, the method yet further includes forming a microlens structure on the UV light filter.

The present technology provides numerous benefits over conventional pixels by reducing or eliminating the amount of photoluminescent material, such as quantum dots, that generate blue light. In conventional photoluminescent pixels, the blue photoluminescent material that generates the pixels' blue light often has a lower quantum efficiency and shorter lifetime than the longer-wavelength photoluminescent material, such as green and red photoluminescent materials. These deficiencies are often corrected by incorporating additional blue photoluminescent material in a redundant subpixel and using a blue light emitting diode to activate light emission all the photoluminescent materials (e.g., red, green, and blue photoluminescent materials). In embodiments of the present technology, a stacked LED structure that includes stacked blue and UV LED structures is operable to provide UV light to the green and red photoluminescent materials while replacing the blue photoluminescent material with the blue light provided by the blue LED structure. The shorter-wavelength UV light increases the quantum efficiency of the light emitted by the green and red photoluminescent materials while reducing the problems with the blue photoluminescent material. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a flowchart with selected operations of an exemplary method of fabricating a pixel according to embodiments of the present technology.

FIG. 2A shows a simplified cross-sectional view of an exemplary pixel structure according to embodiments of the present technology.

FIG. 2B shows a bird's-eye view of an arrangement of pixel structures according to embodiments of the present technology.

FIGS. 3A-L show the development of a portion of an exemplary pixel according to embodiments of the present technology.

FIG. 4A-D show the development of an exemplary pixel using thermal imprint lithography according to embodiments of the present technology.

FIG. 5A-C show the development of an exemplary pixel using photoluminescent material patterned and curing according to embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Technological advances in high-resolutions displays include the development of micro-light-emitting-diodes (μLEDs) from inorganic semiconductor materials and the use of photoluminescent materials like quantum dots in the displays. μLEDs are made of layers of semiconductor materials, such as indium gallium nitride (InGaN), that can be arranged to emit light of a specific peak emission wavelength when excited by an applied electric field. Semiconductor fabrication processes are used to make μLEDs having a longest dimension of less than or about 50 μm and operable to emit red, green, or blue light. Quantum dots are nanometer-sized particles of inorganic materials that can emit light of a particular color after being excited by more energetic light. The color of the emitted light may depend on one or more characteristics of the particles, including their size, shape, and composition, among other characteristics. For quantum dots made of inorganic semiconductor materials, the color of the light they emit depends on an energy gap between the conduction band and the valence band of the dots. When the quantum dots are excited, one or more electrons jump from the lower-energy conduction band to the higher-energy valence band. As the excited electrons fall back down to the conduction band, they emit light having a color that depends on the size of the energy gap between the valence band and the conduction band. The narrower the energy gap, the more the emitted light is shifted to the red, while the wider the energy gap, the more the emitted light is shifted to the blue. By adjusting one or more characteristics of the quantum dots that change the energy gap between the conduction and valence bands, quantum dots can be made that emit light of practically any color in the visible spectrum.

Additional advances have combined μLEDs and quantum dots in a high-resolution display. The μLEDs are independently switched on and off by electronic circuitry in a backplane control panel to generate source light that photoexcites the quantum dots. The more energetic μLED source light, such as blue or ultraviolet light, excites the quantum dots and causes them to emit light of a specific, less-energetic, color such as blue, green, orange, or red light. The excited quantum dots can emit light with improved emissions characteristics, such as a narrower band full-width-half-maximum wavelength spectrum, than the μLEDs. The ability of the quantum dots to emit a sharper color of light reduces the number of color filters and polarizers needed in a display to block unwanted colors of light from contaminating the displayed images. In many cases, the quantum-dot-containing displays are brighter, higher-contrast, and more energy-efficient than μLED displays that lack quantum dots. The combination of the μLEDs and the quantum dots produces a more energy-efficient high-resolution display with an increased number of pixels per square inch (ppi), and a sharper, more accurate color gamut, among other enhancements.

Unfortunately, challenges remain in the development of high-resolution displays that combine μLEDs with photoluminescent materials like quantum dots. One challenge is the instability of blue-light-emitting quantum dots over the operating lifetime of a display. The blue-light-emitting quantum dots can have a more rapid reduction in quantum efficiency over time than quantum dots emitting at longer wavelengths, such as green- and red-light emitting quantum dots. Conventional strategies to compensate for the loss of blue light include providing an additional blue light emitting subpixel in each pixel of the display. Conventional strategies also include using a blue-light-emitting μLED to excite the quantum dots. As the blue light emitted from the blue-light-emitting quantum dots starts to decrease over time, more blue light emitted by the μLED is provided to compensate. Unfortunately, using blue light to excite the longer wavelength emitting quantum dots is less efficient than using more energetic ultraviolet light. The reduction in quantum efficiency can be especially steep when the blue light is exciting red-light emitting quantum dots.

The present technology addresses these and other problems by forming a stacked LED structure and combining it with photoluminescent materials. In embodiments, the stacked LED structure includes both a blue light emitting LED and an ultraviolet light emitting LED. For subpixels which have a photoluminescent region that contain longer-visible-wavelength-light-emitting photoluminescent materials, such as green- or red-light emitting quantum dots, the stacked LED structure emits ultraviolet light from the ultraviolet-light-emitting LED. The ultraviolet light provided by the ultraviolet-light-emitting LED (UV LED) is converted at higher quantum efficiencies by the photoluminescent materials than blue light. For blue subpixels, the stacked LED structures emit blue light from the blue light emitting LED through a region that lacks photoluminescent materials. In these embodiments, the blue light emitted by the LED replaces the blue light that would have been emitted by a photoluminescent material such as blue-light-emitting quantum dots. The absence of blue-light-emitting quantum dots eliminates the problem with short lifetime of these quantum dots compared to longer-wavelength-light-emitting quantum dots.

Embodiments of the present technology include the selective activation of a subset of LEDs in the stacked LED structure depending on the type of photoluminescent region being illuminated. In embodiments, an ultraviolet-light-emitting LED may be selectively activated to emit ultraviolet light into a photoluminescent region containing green- or red-light emitting quantum dots. Other LEDs in the stacked LED structure, such as a blue-light-emitting LED, are not activated for subpixels containing these photoluminescent regions. In contrast, a blue-light-emitting LED in the stacked LED structure may be selectively activated to emit blue light into a non-photoluminescent region that lacks a photoluminescent material. Other LEDs in the stacked LED structure, such as an ultraviolet-light-emitting LED, are not activated for subpixels containing these non-photoluminescent regions. The selective activation of a subset of LEDs in the stacked LED structure, depending on the type of photoluminescent material (or lack thereof) in the subpixel, reduces the number of color filters needed by the display. Selective activation can also reduce blue tinting in a display caused by blue light leaking into non-blue subpixels when all the subpixels are illuminated by unstacked, blue-light-emitting LED structures.

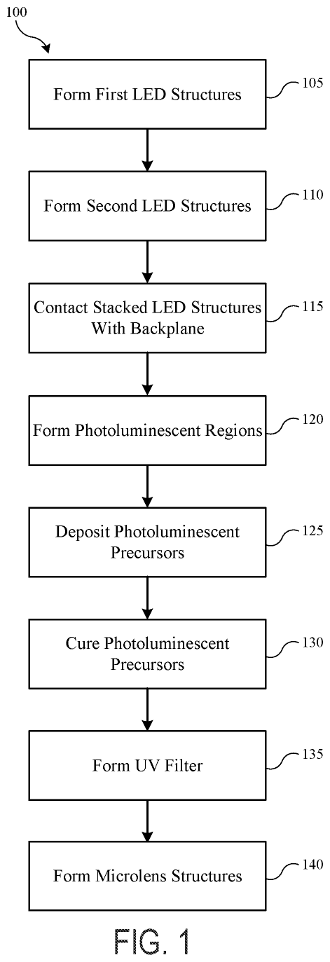

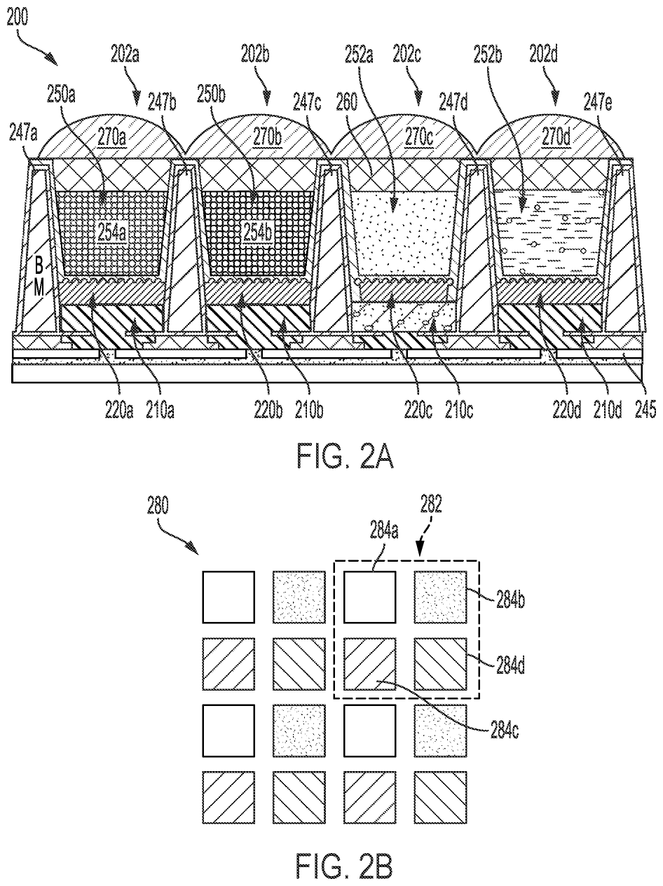

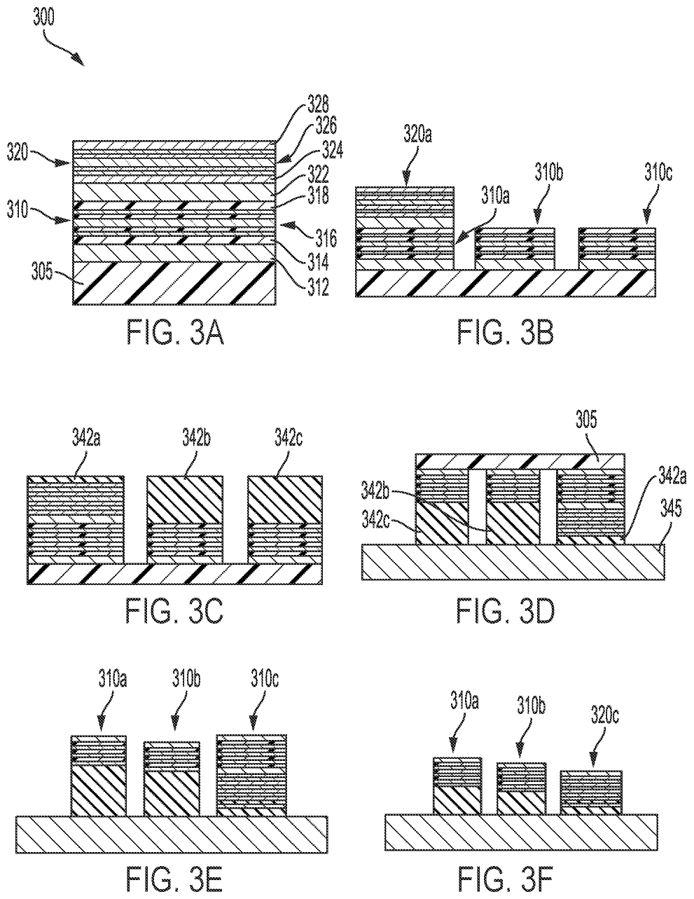

FIG. 1 shows a flowchart with selected operations in method 100 of fabricating a pixel according to embodiments of the present technology. Method 100 may or may not include one or more operations prior to the initiation of the method, including front-end processing, deposition, etching, polishing, cleaning, or any other operations that may be performed prior to the described operations. The method may include optional operations, which may or may not be specifically associated with some embodiments of methods according to the present technology. Method 100 describes operations to form embodiments of pixel structures, one of which is shown in a simplified schematic form as pixel structure 200 in FIG. 2A. The cross-sectional view of pixel structure 200 in FIG. 2A is a split-open cross-sectional view that shows the pixel structure, such as pixel structure 282 shown in FIG. 2B, that is cut between a first and second pair of subpixels and split open to reveal a cross-sectional liner arrangement of red, green, blue, and blank subpixels 202a-d. FIG. 2A illustrates only partial schematic views with limited details. In further embodiments that are not illustrated, exemplary pixel structures may contain additional layers, regions, and materials, having aspects as illustrated in the figures, as well as alternative structural and material aspects that may still benefit from any of the aspects of the present technology.

Method 100 includes forming a first LED structure on a substrate at operation 105. In embodiments, the first LED structure may be a μLED structure operable to emit blue light or ultraviolet light. In some embodiments where the substrate is removed to expose a surface upon which a photoluminescent region is formed, the first LED structure may be operable to emit ultraviolet light. In additional embodiments, where the substrate forms a backplane in electronic communication with the first LED structure, the first LED structure may be operable to emit blue light having a peak emission wavelength in the visible blue portion of the visible spectrum. In further embodiments, the first LED structure may be operable to emit blue light characterized by a peak emission wavelength of greater than or about 420 nm, greater than or about 430 nm, greater than or about 440 nm, greater than or about 450 nm, greater than or about 460 nm, greater than or about 470 nm, greater than or about 480 nm, greater than or about 490 nm, or more. In the embodiment of pixel structure 200 shown in FIG. 2A, the first LED structures 210a-d formed on substrate 205 are operable to emit blue light.

Method 100 further includes forming a second LED structure on the first LED structure at operation 110. In some embodiments, where the second LED structure is formed between the substrate and the first LED structure, the second LED structure may be operable to emit light with a peak emission wavelength that is longer than the peak emission wavelength of the light emitted by the first LED structure. Longer wavelength light emitted by the second LED structure is less likely to be absorbed and create ionizing conditions as it travels through portions of the first LED structure and out of the pixel structure. In some of these embodiments, the second LED structure may emit longer-wavelength blue light and the first LED structure may emit shorter-wavelength ultraviolet light. In additional embodiments, where the second LED structure is formed between the first LED structure and a photoluminescent region or non-photoluminescent region, the second LED structure may be operable to emit light with a peak emission wavelength that is shorter than the peak emission wavelength of the light emitted by the first LED structure. In some of these embodiments, the second LED structure may emit shorter-wavelength ultraviolet light and the first LED structure may emit longer-wavelength blue light. In further embodiments the second LED structure may be operable to emit ultraviolet light charactered by a peak emission wavelength less than or about 405 nm, less than or about 400 nm, less than or about 395 nm, less than or about 390 nm, less than or about 385 nm, less than or about 380 nm, less than or about 375 nm, less than or about 370 nm, less than or about 365 nm, less than or about 360 nm, less than or about 355 nm, less than or about 350 nm, or less. In the embodiment of pixel structure 200 shown in FIG. 2A, the second LED structures 220a-d formed on first LED structures 210a-d are operable to emit ultraviolet light.

In embodiments, the first and second LED structures may be gallium-and-nitrogen-containing LED structures. In further embodiments, the first and second LED structures may be a gallium nitride LED structure that is epitaxially formed on a substrate or a previously formed LED structure. In additional embodiments, the substrate may be a silicon substrate or a sapphire substrate, among other kinds of substrates. In additional embodiments, the first and second LED structures may further include an n-doped GaN layer and a p-doped GaN layer. Formed between the n-doped and p-doped GaN layers is a multiple-quantum-well (MQW) region where the light emitted by the LED structure is generated. The first and second LED structures may further include an electrically conductive N-pad contact that forms a pathway for electrical current to pass through the n-doped GaN layer. The first and second LED structures may also include an electrically conductive P-pad contact that forms a pathway for electrical current to pass through the p-doped GaN layer. The N-pad and P-pad contacts may be connected to electrically conducive layers in an LED subpixel or directly connected to contacts in the control circuitry of a backplane. In embodiments, electrical signals from the control circuitry create a flow of electrical current through the first and second LED structures that causes light emission from the MQW regions of the structures. In additional embodiments, the MQW region is formed to emit light characterized by a repeatable peak intensity wavelength and quantum efficiency for an applied electrical signal (e.g., electrical current and/or voltage). In embodiments, the peak intensity wavelength of the light emitted from the MQW region may be a blue light wavelength or an ultraviolet light wavelength.

Method 100 may further include contacting the stacked LED structures, which include the first and second LED structures, with a backplane at operation 115. In embodiments, the backplane may include a contacts formed in semiconductor layer that independently address the first and second LED structures. In embodiments, the contacts may be made of an electrically conductive material such as copper, aluminum, gold, tungsten, chromium, or nickel, among other electrically conductive materials. In still further embodiments, the first and second LED structures may be positioned between one or more transparent electrically conductive layers that form part of the electrical conduction pathway between the first and second LED structures and the contacts in the backplane. In additional embodiments, the transparent conductive layers may be made of indium tin oxide or indium zinc oxide, among other transparent conductive materials. In yet further embodiments, a mirror layer may be positioned adjacent to the one or more transparent electrical layers to reflect light emitted by the LED structures towards the photoluminescent regions and non-photoluminescent regions. In more embodiments, the mirror layer may be made of one or more reflective metals such as copper, aluminum, chromium, silver, platinum, or molybdenum, among other reflective metals. In still further embodiments, an electrically conductive bonding layer that bonds the stacked LED substrate to the backplane may be positioned between the mirror layer and the backplane. In more embodiments, the electrically conductive bonding layer may be made of one or more conductive materials such as tin, gold, or indium, among other conductive materials. In the embodiment of pixel structure 200 shown in FIG. 2A, the backplane 245 is shown positioned below the stacked LED structures that include the second LED structures 220a-d positioned on the first LED structures 210a-d formed on first LED structure 210 is operable to emit ultraviolet light.

Method 100 may also include forming photoluminescent regions (and non-photoluminescent regions) on the stacked LED structures at operation 120. In embodiments, photoluminescent regions are regions that include one or more photoluminescent materials, such as quantum dots, that are operable to absorb light emitted from the first or second LED structures in the stacked LED structures and emit light with specific color characteristics. In further embodiments, non-photoluminescent regions may have the same structural and material characteristics as the photoluminescent regions except they are free of a photoluminescent material. In still further embodiments, the non-photoluminescent regions may include a gas or vacuum with low light absorbing characteristics at the wavelengths of light emitted by the first and second LED structures. In the embodiment shown in FIG. 2A, pixel structure 200 includes photoluminescent regions 250a-c and non-photoluminescent regions 252a-b.

In embodiments, the photoluminescent and non-photoluminescent regions may be formed in part from subpixel isolation structures. In further embodiments, the pixel isolation structures reduce the crosstalk generated by light from adjacent and nearby subpixels. In embodiments, the reduction in the intensity of light from adjacent and nearby pixels may be greater than or about 50%, greater than or about 60%, greater than or about 70%, greater than or about 80%, greater than or about 90%, greater than or about 95%, greater than or about 99%, or more.

In further embodiments, the subpixel isolation structures may extend above and around the stacked LED structures. In yet further embodiments, the subpixel isolation structures may extend adjacent to and below the contact regions for the stacked LED structures and may further extend down to the backplane of the pixel structure. In more embodiments, the subpixel isolation structures may include a core column of pixel isolation material that is covered by one or more additional layers of material, such as a layer of reflective material such as aluminum or copper. In embodiments, the material in the core column may include a metal or a dielectric material, among other types of materials. In further embodiments, the metal material may include one or more of silicon, tungsten, copper, and aluminum, among other metals. In yet further embodiments, the dielectric material may include one or more of silicon oxide, silicon nitride, silicon carbide, a photoresist material, or a dielectric organic-polymer material, among other dielectric materials. In still further embodiments, the pixel isolation structures may have a height of greater than or about 2.5 μm, greater than or about 5 μm, greater than or about 7.5 μm, greater than or about 10 μm, greater than or about 12.5 μm, greater than or about 15 μm, greater than or about 17.5 μm, greater than or about 20 μm, or more. In yet additional embodiments, the pixel isolation structures may have a width of greater than or about 1 μm, greater than or about 2 iim, greater than or about 3 μm, greater than or about 4 μm, greater than or about 5 μm, greater than or about 6 μm, greater than or about 7 μm, greater than or about 8 μm, greater than or about 9 μm, greater than or about 10 μm, or more. In still further embodiments the pixel isolation structures may have a height-to-width aspect ratio that is greater than or about 1.5:1, greater than or about 2:1, greater than or about 2.5:1, greater than or about 3:1, greater than or about 3.5:1, greater than or about 4:1, greater than or about 4.5:1, greater than or about 5:1, or more. In the embodiment shown in FIG. 2A, pixel structure 200 includes pixel isolation structures 247a-e.

Method 100 still further includes depositing photoluminescent precursors in the photoluminescent regions of the pixel structure at operation 125. In embodiments, the photoluminescent precursors may be a mixture or slurry that includes a photo-curable fluid and one or more photoluminescent particles or compounds. In further embodiments, the one or more photoluminescent compounds may include quantum dot materials that are operable to emit light with specific color characteristics when excited by a source light. In additional embodiments, these quantum-dot materials may include nanoparticles made of one or more kinds of inorganic semiconductor materials such as indium phosphide, zinc selenide, zinc sulfide, silicon, silicates, and graphene, and doped inorganic oxides, among other semiconductor materials. In more embodiments, the photo-curable fluid may include one or more cross-linkable compounds, a photo-initiator, and a color conversion agent. In additional embodiments, the cross-linkable compounds may include monomers that form a polymer when cured. In more embodiments, the monomers may include acrylate monomers, methacrylate monomers, and acrylamide monomers.

In yet more embodiments, the cross-linkable compounds may include a negative photoresist material such as SU-8 photoresist. In further embodiments, the photo-initiator may include phosphine oxide compounds and keto compounds, among other kinds of photo-initiator compounds that generate radicals that initiate the curing of unsaturated compounds when excited by ultraviolet light. Commercially available photo-initiator compounds include Irgacure 184, Irgacure 819, Darocur 1173, Darocur 4265, Darocur TPO, Omnicat 250, and Omnicat 550, among other photo-initiators.

Method 100 also includes curing the photoluminescent precursor to form a photoluminescent material in at least one of the photoluminescent regions at operation 130. In embodiments, the curing operation may include selectively exposing the photoluminescent precursor in one of the photoluminescent regions to a curing light that coverts the photoluminescent precursor into the photoluminescent material. In still further embodiments, the curing light may be characterized by a peak emission wavelength short enough to activate one or more of the photo-curable compounds in the photo-curable fluid of the photoluminescent precursor. In yet more embodiments, the curing light may be characterized by a peak emission wavelength of less than or about 405 nm, less than or about 400 nm, less than or about 395 nm, less than or about 390 nm, less than or about 385 nm, less than or about 380 nm, less than or about 375 nm, less than or about 370 nm, less than or about 365 nm, less than or about 360 nm, less than or about 355 nm, less than or about 350 nm, less than or about 340 nm, less than or about 330 nm, less than or about 320 nm, less than or about 310 nm, less than or about 300 nm, or less. In still further embodiments, the curing light may be supplied by the stacked LED structure. In these embodiments, supplying the curing light from the stacked LED structure may permit the self-alignment of the photoluminescent material in the photoluminescent region with the stacked LED structure. The self-alignment of the photoluminescent material with the stacked LED structure is increasingly beneficial as the size of the subpixels decreases and the pixel density increases.

In embodiments, the formation of the photoluminescent material in the photoluminescent regions may include sequential operations to form photoluminescent material operable to emit light characterized by a specific peak intensity wavelength in one of the subpixels of the LED pixel structure. In further embodiments, the sequential operations may include forming first photoluminescent material that includes red light emitting quantum dots in a first photoluminescent region of the LED pixel structure and forming a second photoluminescent material that includes green light emitting quantum dots in a second photoluminescent region of the LED pixel structure. In further embodiments, the LED pixel structure may be free of photoluminescent material that includes blue light emitting quantum dots. In these embodiments, blue light emitted from the stacked LED structure may provide light to a non-photoluminescent region. Following the formation of the photoluminescent materials in the photoluminescent regions, each LED pixel may include red, green, and blue subpixels, as well as a redundant subpixel. In the embodiment shown in FIG. 2A, pixel structure 200 includes photoluminescent materials 254a-b in photoluminescent regions 350a-b.

Method 100 yet further includes forming an ultraviolet (UV) filter on the photoluminescent regions and non-photoluminescent regions in operation 135. In embodiments, the UV filter may be a dielectric layer that absorbs UV light generated by the stacked LED structures in the subpixel while transmitting the visible light emitted by the photoluminescent material in the photoluminescent regions. In further embodiments, the dielectric layer may be a silicon oxide layer deposited by chemical vapor deposition or physical vapor deposition. In still additional embodiments, the UV filter may be made from organic polymers such as polyacrylates, polymethyl methacrylates, and copolymers of polyacrylates and polymethyl methacrylates. In yet further embodiments, the UV filter may be made from commercially available materials such as Tinuvin CarboProtect from BASF, and the Eversorb series from Everlight. In embodiments, the UV filter may reduce the percentage of UV light in the total light emitted from the pixel structure to less than or about 5%, less than or about 2.5%, less than or about 1%, less than or about 0.5%, less than or about 0.1%, less than or about 0.05%, less than or about 0.01%, or less. In additional embodiments, the UV filter may transmit visible light from the pixel structure at greater than or about 50%, greater than or about 75%, greater than or about 85%, greater than or about 90%, greater than or about 95%, greater than or about 99%, or more. In the embodiment shown in FIG. 2A, pixel structure 200 includes UV filter 260.

Method 100 still also includes forming microlenses on the UV filter in operation 140. In embodiments, microlenses may be formed on two or more of the subpixels, three or more of the subpixels, and all of the subpixels in the pixel structure. In additional embodiments, the microlenses may be convex-shaped lenses, concave-shaped lenses, Fresnel-shaped lenses, among other lens shapes. In further embodiments, the microlenses may be made of inorganic or organic materials that can transmit the visible light emitted from the subpixels. In additional embodiments, the microlenses may be made of polymers such as polydimethylsiloxanes, polyacrylates, polymethyl methacrylates, polybutyl methacrylates, polystyrenes, and poly(benzyl methacrylates), among other polymers. In more embodiments, the microlenses may be made of inorganic materials such as silica, zinc oxide, and aluminum oxide, among other inorganic materials. The microlenses bend and focus the light emitted by the pixel structure to increase image quality for specific applications such as VR headsets and AR glasses, among other applications. In the embodiment shown in FIG. 2A, pixel structure 200 includes microlenses 270a-d.

FIG. 2B shows birds-eye view of an arrangement of pixel structures 280 that includes a group of pixels 282 that each include four subpixels 284a-d. In the embodiment shown in FIG. 2B, the pixels 282 and the subpixels 284a-d that make up each of the pixels are square shaped. It will be appreciated that embodiments of subpixels 284a-d may have additional shapes, such as rectangular-shaped, parallelogram-shaped, trapezoidal-shaped, pentagonal-shaped, hexagonal-shaped, heptagonal-shaped, octagonal-shaped, nonagonal-shaped, circular-shaped, and elliptical-shaped, among other kinds of shapes. In still further embodiments, the pixels 282 may also be arranged in additional shapes such as rectangular-shaped, parallelogram-shaped, trapezoidal-shaped, circular-shaped, and elliptical-shaped, among other kinds of shapes. In more embodiments, each of the subpixels 284a-d may be characterized by a longest dimension (e.g., a diagonal length) that is less than or about 10 μm, less than or about 9 μm, less than or about 8 inn, less than or about 7 μm, less than or about 6 μm, less than or about 5 μm, or less. In still more embodiments, each of the pixels 202 may be characterized by a longest dimension of les s than or about 25 inn, less than or about 22.5 inn, less than or about 20 inn, less than or about 17.5 inn, less than or about 15 inn, less than or about 12.5 inn, less than or about 10 inn, or less. In still further embodiments, the pixel structures 280 may be part of a larger arrangement of pixel structures that make up at least a portion of a high pixel density display. In embodiments, the display may be characterized by a pixel density of greater than or about 1000 ppi, greater than or about 1250 ppi, greater than or about 1500 ppi, greater than or about 1750 ppi, greater than or about 2000 ppi, greater than or about 2500 ppi, greater than or about 2750 ppi, greater than or about 3000 ppi, or more.

Embodiments of the present technology also include fabrication methods where one or more LED structures are removed from the stacked LED structure before the photoluminescent region is formed on the remaining LED structure. In these embodiments, the as-deposited LED layers are formed into the stacked LED structures that each include at least a first LED structure and a second LED structure positioned on the first LED structure. In one subgroup of the stacked LED structures, the first LED structure is removed and a photoluminescent region or non-photoluminescent region is formed on the second LED structure. In another subgroup of the stacked LED structures, the second LED structure is removed and a photoluminescent region or non-photoluminescent region is formed on the first LED structure. In embodiments, the originally-formed stacked LED structures are converted into subgroups of single LED structures operable to emit light of different peak emission wavelengths. For example, a first subgroup of single LED structures may be operable to emit ultraviolet light and a second subgroup of single LED structures may be operable to emit blue light.

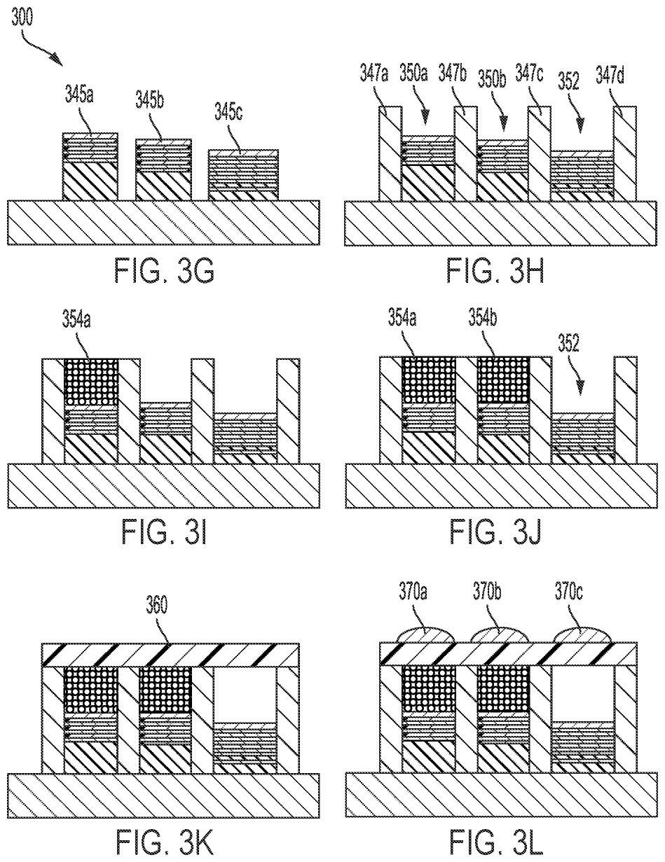

FIGS. 3A-L show the development of a pixel structure 300 made according an embodiment of a fabrication method that forms stacked LED structures into subgroups of single LED structures operable to emit different wavelengths of light. FIG. 3A shows continuous layers of materials that make up a first LED structures 310 and a second LED structures 320 that are formed on a substrate 305. In embodiments, the substrate 305 may include silicon or sapphire, among other substrate materials. In additional embodiments, the continuous layers of materials may include the layers for the first LED structures 310, which include an undoped GaN region 312, a first p-doped (or n-doped) GaN region 314, a first quantum well structure 316, and a first n-doped (or p-doped) GaN region 318. In further embodiments, the continuous layers of material also include the layers that make the second LED structures 320 formed on the layers that make up the first LED structures 310. In still further embodiments, the second LED structures 320 include a second undoped GaN region 322, a second p-doped (or n-doped) GaN region 324, a second quantum well structure 326, and a second n-doped (or p-doped) GaN region 328. In more embodiments, the first quantum well structure 316 determines the color of light emitted from the first LED structure 310 and the second quantum well structure 326 determines the color of light emitted by the second LED structure 320.

FIG. 3B shows the continuous layers of materials formed into discrete LED structures on substrate 305. In the embodiment shown, the continuous layer of materials is formed into a stacked LED structure 340, which includes a first LED structure 310a formed on a second LED structure 320a, and adjacent first LED structures 310b-c. Also in the embodiments shown, second LED structures have been removed for the adjacent first LED structures 310b-c.

FIG. 3C shows contact regions 342a-c formed on the second LED structure 320a and first LED structures 310b-c, respectively. In embodiments, the contact regions 342a-c may be made of one or more electrically conductive materials such as a metal, a metal alloy, or an electrically conductive metal oxide, among other electrically conductive materials. In embodiments, the contact regions 342a-c may be made of one or more metals such as copper, aluminum, gold, tungsten, chromium, and nickel, among other metals.

FIG. 3D shows a backplane 345 attached to the contact regions 342a-c in the pixel structure 300. The backplane 345 includes electronic circuitry to regulate electrical current passing through the contact regions 342a-c to the second LED structure 320a and first LED structures 310b-c, respectively. In further embodiments, the backplane 345 may include CMOS circuitry that includes CMOS transistors that are operable to turn on and off the flow of electrical current to the first and second LED structures.

FIG. 3E shows the substrate 305 removed from the first LED structures 310a-c in the pixel structure 300. In embodiments, the substrate 305 may be removed by one or more operations, including etching the substrate and detaching the substrate from the first LED structures 310a-c. In embodiments, a detachment operation may include detaching the substrate 305 from a detachment layer (not shown) positioned between the substrate and the undoped GaN regions 312 of the first LED structures 310a-c.

FIG. 3F shows the first LED structure 310a removed from the second LED structure 320a in the pixel structure 300. The removal of the first LED structure 310a provides a base region for a group of subpixels that are operable to emit light of a second peak emission wavelength from the second LED structure 320a. This group of subpixels is complemented by another group of subpixels with a base region that includes the first LED structures 310b-c that are operable to emit light into the subsequently formed photoluminescent regions as shown in FIGS. 3G-L.

FIG. 3G shows the inclusion of optically transparent regions 345a-c on the first and second LED structures 310a-b and 320c, respectively, in the pixel structure 300. In embodiments, the optically transparent regions 345a-c may be characterized by a high optical transmittance at the wavelengths of light emitted by the first and second LED structures 310a-b and 320c. In further embodiments the optically transparent regions 345a-c may be characterize by an optical transmittance at these wavelengths of greater than or about 80%, greater than or about 85%, greater than or about 90%, greater than or about 95%, greater than or about 99%, or more. In further embodiments, the optically transparent regions 345a-c may include an optically transparent organic polymer or an optically transparent inorganic material. In still further embodiments, the optically transparent inorganic material may include an electrically conductive optically transparent material such as indium-tin-oxide (ITO).

FIG. 3H shows the inclusion of subpixel isolation structures 347a-d between the first and second LED structures 310a-b and 320c in the pixel structure 300. In embodiments, the subpixel isolation structures 347a-d may be made of reflective and conductive materials (e.g., a metal) and may be surrounded by electrically insulating passivation layers to prevent the subpixel isolation structures from shorting the contact regions 342a-c and the first and second LED structures 310a-b and 320c. The subpixel isolation structures 347a-d form sidewalls for the first and second photoluminescent regions 350a-b and the non-photoluminescent region 352.

FIG. 3I shows the inclusion of a first photoluminescent material 354a in the first photoluminescent region 350a in the pixel structure 300. In embodiments, the first photoluminescent material 354a may include a quantum dot material that is operable to emit red light.

FIG. 3J shows the inclusion of a second photoluminescent material 354b in the first photoluminescent region 350b in the pixel structure 300. In embodiments, the first photoluminescent material 354b may include a quantum dot material that is operable to emit red light.

In embodiments of the present technology, the non-photoluminescent region 352 is free of a third photoluminescent material operable to emit light with a peak emission wavelength shorter than the first and second photoluminescent materials, such as blue light. In embodiments, the blue light emitted by the second LED structure 320c passes through the optically transparent region 345c and the non-photoluminescent region 352 without color conversion from a photoluminescent material. This eliminates the need for a blue light emitting photoluminescent material, such as blue quantum dots, which often have shorter lifetimes than longer wavelength emitting quantum dots, such as green- and red-light emitting quantum dots.

FIG. 3K shows the inclusion of an ultraviolet (UV) filter 360 on the first LED structures 310a-b and the second LED structure 320c in the pixel structure 300. The UV filter 360 absorbs ultraviolet light generated by the first LED structures 310a-b while passing the visible light emitted from the photoluminescent regions 350a-b and non-photoluminescent region 352. In some embodiments, the UV filter 360 may be absent or replaced by a more optically transmissive layer over the non-photoluminescent region 352. In these embodiments, the second LED structure 320c is operable to emit light with a peak emission wavelength in the blue portion of the electromagnetic spectrum and significantly lower emission intensity in the ultraviolet portion of the spectrum. The reduced ultraviolet light emissions from the non-photoluminescent region 352 reduced the benefit of positioning a UV filter 360 over the region to absorb ultraviolet light emitting from the non-photoluminescent region.

FIG. 3L shows the inclusion of microlenses 370a-c on the UV filter 360 in the pixel structure 300. In embodiments, the microlenses 370a-c are operable to concentrate and align the light emitted from the photoluminescent regions 350a-b and non-photoluminescent region 352, respectively. In further embodiments, the microlenses 370a-c may be made from an organic polymer or an inorganic dielectric material such as silicon oxide.

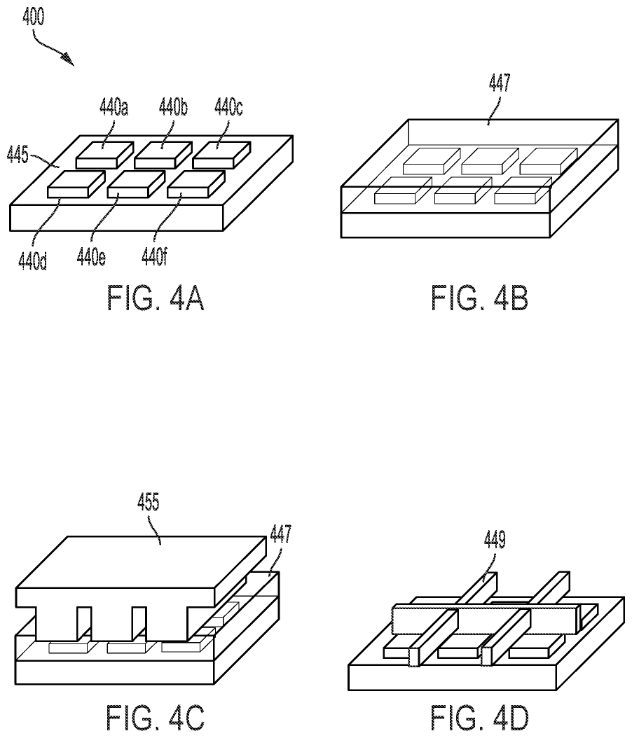

In additional embodiments of the present technology, photoluminescent regions and non-photoluminescent regions may be formed on the LED structures using thermal imprinting lithography. This technique can replace a complex sequence of operations that include depositions, mask patterning, etching, and mask removal with a simplified series of operations that include the deposition of a subpixel isolation material on the LED structures and thermal imprinting of photoluminescent and non-photoluminescent regions on the subpixel isolation material. FIGS. 4A-D show the development of an exemplary pixel structure 400 using thermal imprint lithography according to embodiments of the present technology.

FIG. 4A shows a simplified planar view of a set of stacked LED structures 440a-f formed on a backplane 445 that includes electronic circuitry to regulate electrical signals that activate the illumination of LEDs in the stacked LED structures 440a-f. In further embodiments, the backplane 445 may include CMOS circuitry that includes CMOS transistors that are operable to turn on and off the flow of electrical current to the stacked LED structures 440a-f.

FIG. 4B shows a subpixel isolation material 447 deposited on the stacked LED structures 440a-f and the backplane 445. In embodiments, the subpixel isolation material 447 may include a black matrix material that can cure at elevated temperatures while pressing with an imprint stamp. In further embodiments, the subpixel isolation material 447 may include a reflective polymer material that reflects light across the range of wavelengths emitted by the stacked LED structures 440a-f and the photoluminescent material in the photoluminescent regions formed in part by the subpixel isolation material.

FIG. 4C shows an imprint stamp 455 in contact with the subpixel isolation material 447. In embodiments, the imprint stamp 455 and the substrate is heated to an elevated temperature where the subpixel isolation material 447 will cure to form the finished isolation structure. In further embodiments, the imprint stamp 455 includes a die having a pattern operable to form photoluminescent and non-photoluminescent regions in the subpixel isolation material 447. When the imprint stamp 455 is pressed into the subpixel isolation material 447, the pattern in the die displaces or removes a portion of the subpixel isolation material to form the photoluminescent and non-photoluminescent regions.

FIG. 4D shows the patterned subpixel isolation material 449 that remains on the pixel structure 400 after the imprint stamp 455 is removed from contact with the pixel structure. In embodiments, the patterned subpixel isolation material 449 includes photoluminescent and non-photoluminescent regions formed over the stacked LED structures 440a-f that were previously filed with the subpixel isolation material 447.

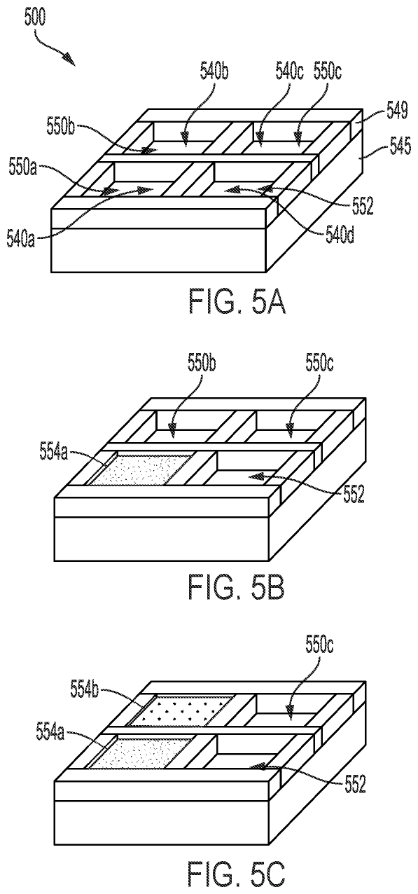

In further embodiments of the present technology, photoluminescent materials may be formed in photoluminescent regions by spin-coating and curing photoluminescent precursors on the photoluminescent regions. FIGS. 5A-C show the development of photoluminescent regions containing photoluminescent materials using spin coating and curing techniques according to embodiments of the present technology.

FIG. 5A shows a patterned pixel structure 500 that includes open photoluminescent regions 550a-c and non-photoluminescent region 552. In embodiments, the open photoluminescent regions 550a-c and non-photoluminescent region 552 are formed in part from patterned subpixel isolation material 549 formed over stacked LED structures 540a-f and backplane 545.

FIG. 5B shows a first photoluminescent material 554a formed in photoluminescent region 550a. In embodiments, the first photoluminescent material 554a is formed by applying a first photoluminescent precursor (not shown) on the empty photoluminescent regions 550a-c and non-photoluminescent regions 552 in the patterned pixel structure 500. The first photoluminescent precursor is then selectively cured in the first photoluminescent region 550a while remaining uncured in the other photoluminescent regions 550b-c and non-photoluminescent region 552. In further embodiments, the selective curing of the first photoluminescent precursor in the first photoluminescent region 550a may be performed by selectively irradiating the first photoluminescent region to form a photocured first photoluminescent material 554a. In still further embodiments, the uncured first photoluminescent precursor may be removed from the other photoluminescent regions 550b-c and non-photoluminescent region 552 to form the patterned pixel structure 500 with the photoluminescent region 550a filled with photoluminescent material 554a and the other regions free of the first photoluminescent precursor. In embodiments, the first photoluminescent material 554a may include red quantum dots operable to emit red light when illuminated by the underlying stacked LED structure 540a.

FIG. 5C shows the patterned pixel structure 500 with a second photoluminescent region 550b that includes a second photoluminescent material 554b. In embodiments, the second photoluminescent material 554b is formed by applying a second photoluminescent precursor (not shown) on the empty photoluminescent regions 550b-c and non-photoluminescent region 552 in the patterned pixel structure 500. In further embodiments, the second photoluminescent precursor does not fill photoluminescent region 550a because the region is already filled with the first photoluminescent material 554a. The second photoluminescent precursor is then selectively cured in the second photoluminescent region 550b while remaining uncured in the other photoluminescent region 550c and non-photoluminescent region 552. In still further embodiments, the uncured second photoluminescent precursor may be removed from the other photoluminescent regions 550c and non-photoluminescent region 552 to form the patterned pixel structure 500 with the photoluminescent region 550a filled with the first photoluminescent material 554a, the second photoluminescent region 550b filed with the second photoluminescent material 554b, and the other regions free of photoluminescent precursors. In embodiments, the second photoluminescent material 554b may include green quantum dots operable to emit green light when illuminated by the underlying stacked LED structure 540b.

In still further embodiments, the third photoluminescent region 550c and the non-photoluminescent region 552 may remain free of a cured photoluminescent material. In these embodiments, the third photoluminescent region 550c may function as a redundant subpixel that is only filled with photoluminescent material if subpixel that includes the first or second photoluminescent regions 550a-b is not functioning correctly. In more embodiments, the non-photoluminescent region 552 is a region through which the light emitted by the stacked LED structure 540d passes along an exit path from the pixel structure 500. In yet more embodiments, the stacked LED structure 540d is operable to emit blue light that complements the red light emitted from the first subpixel that includes the first photoluminescent material 554a and the green light emitted from the second subpixel that includes the second photoluminescent material 554b.

Embodiments of the present technology provide displays that include combinations of stacked LED structures and photoluminescent materials, such as quantum dots. In embodiments, the stacked LED structures provide shorter wavelength light, such as ultraviolet light, to activate photoluminescent materials with increased quantum efficiency. In additional embodiments, the stacked LED structures provide longer wavelength light, such as blue light, to reduce or eliminate blue light emitting quantum dots in the display that are characterized by shorter lifetimes and lower quantum efficiencies. In further embodiments, the present technology includes methods of making displays with stacked LED structures and methods that process stacked LED structures into two or more types of unstacked LED structures operable to emit light with different peak emission wavelengths. These and other embodiments of the present technology provide high-pixel density displays with sharp, accurate color gamuts for incorporation into display devices such as television displays, monitors, portable displays for phones, tablets, and laptop computers, and wearable displays for smart watches, virtural-reality headsets, and augmented-reality glasses, among other devices.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a material” includes a plurality of such materials, and reference to “the precursor” includes reference to one or more precursors and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A pixel structure comprising:
a first light emitting diode structure operable to generate blue light characterized by a peak emission wavelength of greater than or about 450 nm; and
a second light emitting diode structure positioned on the first light emitting diode structure, wherein the second light emitting diode structure is operable to generate ultraviolet light characterized by a peak emission wavelength of less than or about 405 nm.

2. The pixel structure of claim 1, wherein the pixel structure further comprises a photoluminescent region containing a photoluminescent material, wherein the photoluminescent region is positioned on the second light emitting diode structure.

3. The pixel structure of claim 2, wherein the photoluminescent material comprises a red quantum dot material or a green quantum dot material, and wherein the pixel structure is free of a blue quantum dot material.

4. The pixel structure of claim 1, wherein the pixel structure further comprises a backplane in electronic communication with the first light emitting diode structure or the second light emitting diode structure.

5. The pixel structure of claim 4, wherein the backplane is operable to activate only one of the first light emitting diode structure and the second light emitting diode structure.

6. The pixel structure of claim 1, wherein the first light emitting diode structure comprises a blue quantum well stack operable to emit the blue light, and the second light emitting diode structure comprises a UV quantum well stack operable to emit the ultraviolet light.

7. The pixel structure of claim 2, wherein the pixel structure further comprises a UV light filter positioned on the photoluminescent region of the pixel structure.

8. The pixel structure of claim 7, wherein the pixel structure further comprises a microlens structure positioned on the UV light filter.

9. A pixel structure comprising:
a first subpixel that includes:
an ultraviolet light emitting diode structure operable to generate ultraviolet light characterized by a peak emission wavelength of less than or about 405 nm, and
a photoluminescent region containing a photoluminescent material operable to emit red or green light, wherein the photoluminescent region is positioned on the ultraviolet light emitting diode structure; and
a second subpixel that includes:
a blue light emitting diode structure operable to generate blue light characterized by a peak emission wavelength of greater than or about 450 nm, and
a non-photoluminescent region that is free of a photoluminescent material, wherein the non-photoluminescent region is positioned on the blue light emitting diode structure.

10. The pixel structure of claim 9, wherein the non-photoluminescent region has the same volume as the photoluminescent region.

11. The pixel structure of claim 9, wherein the first subpixel further includes a blue light emitting diode structure positioned on an opposite side of the ultraviolet emitting diode structure as the photoluminescent region.

12. The pixel structure of claim 9, wherein the second subpixel further includes an ultraviolet light emitting diode structure positioned between the blue light emitting diode structure and the non-photoluminescent region.

13. The pixel structure of claim 11, wherein the pixel structure further comprises a backplane in electronic communication with the ultraviolet light emitting diode structure of the first subpixel and disconnected from the blue light emitting diode structure of the first subpixel.

14. The pixel structure of claim 9, wherein the pixel structure is free of a blue quantum dot material.

15. A method of fabricating a pixel, the method comprising:
forming a blue light emitting diode structure on a substrate;
forming an ultraviolet light emitting diode structure on the blue light emitting diode structure to make a stacked light emitting diode structure;
forming a photoluminescent region on the stacked light emitting diode structure;
depositing a photoluminescent precursor in the photoluminescent region; and
curing the photoluminescent precursor to form a photoluminescent material, wherein the photoluminescent material is operable to emit red or green light.

16. The method of claim 15, wherein an additional subpixel in the pixel is formed by:
forming an additional blue light emitting diode structure on the substrate;
forming an additional ultraviolet light emitting diode structure on the additional blue light emitting diode structure to make an additional stacked light emitting diode structure;
forming an additional photoluminescent region on the additional stacked light emitting diode structure; and
forming a UV light filter on the additional photoluminescent region,
wherein the additional photoluminescent region is free of a photoluminescent material, and wherein the additional subpixel is operable to emit blue light from the additional blue light emitting diode structure.

17. The method of claim 15, wherein the pixel is free of a blue quantum dot material.

18. The method of claim 15, wherein the method further comprises:
contacting a backplane to a side of the stacked light emitting diode structure that is opposite a side in contact with the substrate, wherein the backplane is operable to be in electronic communication with the stacked light emitting diode structure; and
removing the substrate from the stacked light emitting diode structure, wherein the photoluminescent region is formed on the side of the stacked light emitting diode structure where the substrate is removed.

19. The method of claim 15, wherein the method further comprises forming a UV light filter on the photoluminescent region containing the photoluminescent material.

20. The method of claim 19, wherein the method further comprises forming a microlens structure on the UV light filter.
